(19) United States
(12) Patent Application Publication
(10) Pub. No.: US 2002/0086242 A1
(43) Pub. Date: Jul. 4, 2002

(54) Novel low defect developer rinse process for 0.15 micron cmos technology

(76) Inventors: Mark A. Boehm, Sachse, TX (US); Amy Zhou, Plano, TX (US); Yu-Tai Lee, Plano, TX (US); Ashesh Parikh, Frisco, TX (US); David M. Curran, Plano, TX (US)

Correspondence Address: TEXAS INSTRUMENTS INCORPORATED, P O BOX 655474, M/S 3999, DALLAS, TX, 75265

(21) Appl. No.: 10/005,779

(22) Filed: Nov. 8, 2001

Related U.S. Application Data
(60) Provisional application No. 60/259,309, filed on Dec. 31, 2000.

(51) Int. Cl. G03F 7/30; G03F 7/32; G03F 7/40

(52) U.S. Cl. 430/311; 430/328; 430/331; 430/325

(57) ABSTRACT

Wafer developer solution is removed in a wafer spinning process wherein the wafer is spun for a period of time before a deionized water bath is introduced. The delay allows more developer to be spun off before introducing the water, which eliminates residue and particulates on the wafer surface.

### BACKGROUND AND SUMMARY OF THE INVENTION

The present invention relates to integrated circuit fabrication methods, and particularly to cleanup after development of photoresist.

One of the most ubiquitous process technologies is photolithography. Once a planar layer of photoresist has been exposed with very fine geometries (by a very expensive imaging system), it must be developed. The development process translates the slight intensity variations (in the aerial image which was projected onto the photoresist layer) into physical presence or absence of a developed photoresist layer. The patterned photoresist layer can then be used to mask various other process steps. Thus photoresist technology is one of the essential foundations of progress in microfabrication.

A typical developing process is shown in FIG. 1. At stage a, the resist is placed on the substrate by known means, such as photolithography. The developer is the deposited on the surface covering the resist to induce development of the pattern (stage b). Resist is gradually dissolved at unexposed resist areas. this is called Dark loss. The amount of loss is dependent on the protection ratio of the resin (often referred to as the contrast behavior of the resin). This thins the resin, as shown in stage c. Next, as the wafer is spun, deionized water is introduced to rinse the developing solution from the wafer surface (stage d). The deionized water mixes with the developer solution at the puddles on the wafer surface. This results in ph shock, which causes residue formation in the puddle. After the rinsing process, the developer and water are removed from the surface, but large amounts of particulates in the residue puddle can result in particulate and residue deposit on the surface of the wafer (stage e). This can be a source of yield loss, which has a very direct impact on the profitability of integrated circuit manufacturing.

This residue can be further reduced or eliminated by very long deionized water rinses or processing the wafer through another tool for added rinsing. This extra processing obtains clean wafers but at the cost of process cycle time, throughput, and added equipment requirements.

A Novel Low Defect Developer Rinse Process

The present inventors have realized that the interaction of the developer solution with the rinse water is itself a defect-related variable which can be controlled. The present application discloses a process for rinsing wafers of developer solution that minimizes the process budget that must be allocated to cleaning the wafers In the preferred embodiment, this is done by delaying the introduction of the deionized water rinse for a period of time after the wafer has begun spinning, decreasing the possible interaction time of the DI and the developer solution.

Advantages of the disclosed methods include reduced defects without requiring additional front end floor space or reducing through-put.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a wafer surface with resist and developer, and formation of residue.

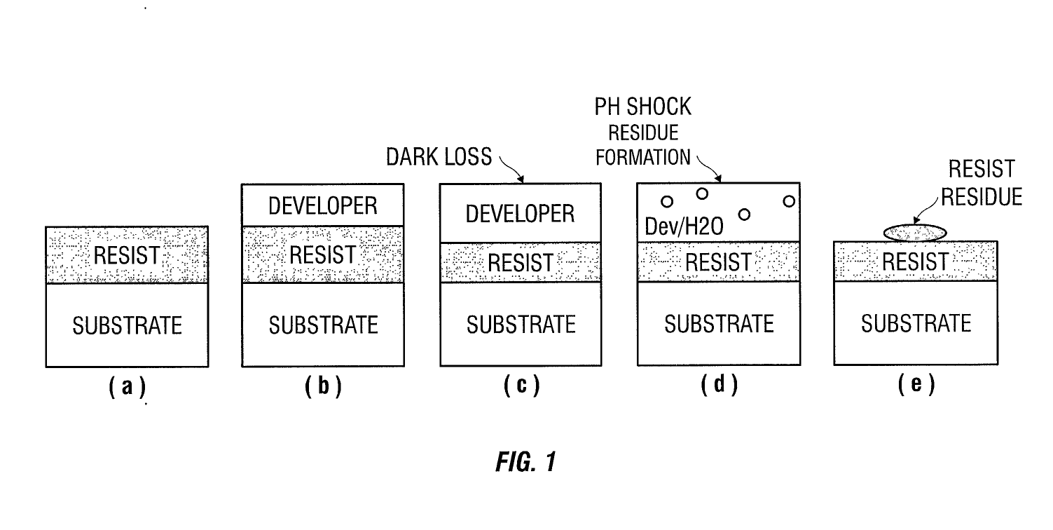

FIG. 2 shows a flow chart of key steps in the innovative process.

FIG. 3 shows a defect map comparing wafers cleaned using conventional and innovative means.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

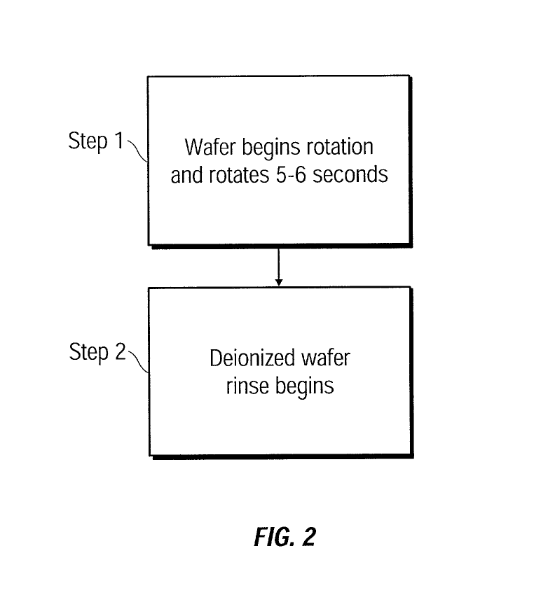

The present application teaches innovations that minimize the amount of residue formation on the wafers so that it can more easily and effectively be dealt with, without the need for excessive water rinsing or added process tools. FIG. 2 shows a flow chart of key steps to the preferred embodiment of the innovative process. After the developer as been added, the wafer must be rinsed and the developer removed. In step 1, the wafer is rotated, but the deionized water rinse is delayed, allowing the wafer to sling off as much developer as possible before introduction of the water, which otherwise would cause ph shock and create residue on the wafer. This delay, in the preferred embodiment, is for as long as possible without allowing the wafer surface to dry substantially. Next, while the wafer is still rotating, the deionized water is added to rinse the wafer, removing excess developer (step 2). By delaying the introduction of the water rinse, a maximum amount of developer is removed before adding the water, which reduces the amount of precipitates and residue formed due to ph shock.

In the preferred embodiment, the wafer is spun at approximately 2000 rpm for twenty or more seconds. It should be noted that in some embodiments, the wafer rotation speed varies, starting at a high velocity and decreasing after a few seconds. In the preferred embodiment, the wafer rotation speed is kept at high velocity during the entire rotation procedure. The wafer is spun for four seconds before the deionized water is used to rinse the surface. This delay allows the developer to be removed as much as possible before adding the water, because the interaction between the developer and the water is a primary source of precipitate and residue. By spinning the wafer several seconds before adding water, more developer is removed, leaving less material for precipitate formation. The preferred embodiment has an upper limit to the spinning time before water is added, because actually drying the wafer (which occurs eventually unless water is added) creates many defects. A key time for practicing the invention is the point at which the wafer surface is just about to dry, maximizing the amount of developer removed before water is added. At 2000 rpm, drying occurs at about 5-6 seconds. Faster spinning dries the wafer sooner.

The precipitates of concern are from the developer solution and undissolved resist residue. Parts of this residue are insoluble in water, and are mechanically rinsed from the wafer surface by the water. The residue and particulates, if they remain on the wafer surface, create blocked pattern defects. These can block etches or implants, creating shorts or bridges that interfere with device performance. A typical developer used in these processes is a 2.38% tetramethyl ammonium hydroxide solution.

The times and speeds of rotation mentioned in this application will of course vary for individual process materials and parameters. In the preferred embodiment, the developer puddle time is about 45 seconds, which produces less resist dark loss that can create more residue defects later in the process. Any time saved during the developer puddle process is used to provide added rinsing to remove more precipitate and residue.

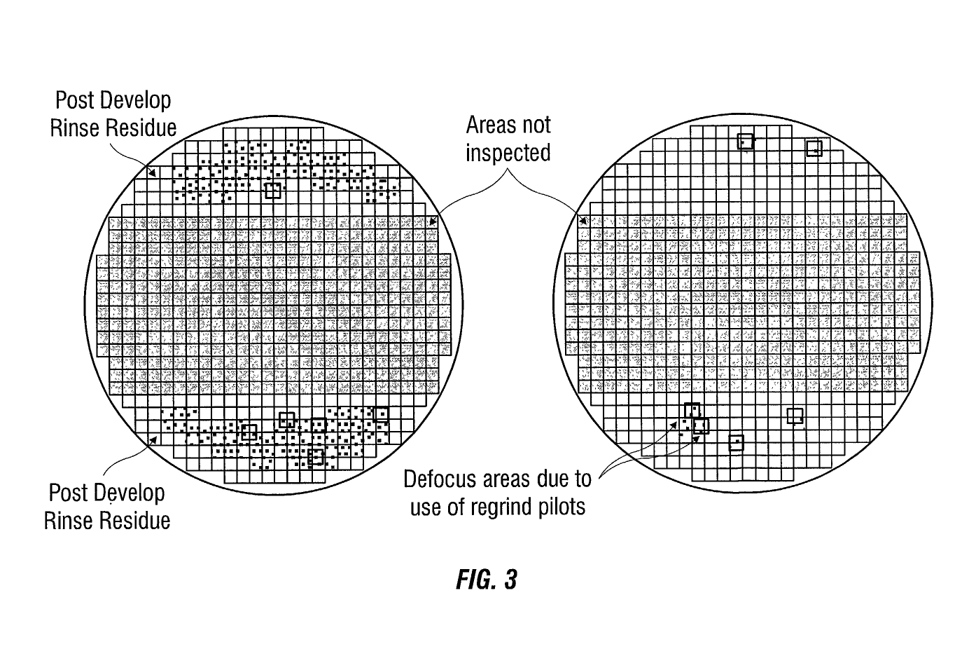

FIG. 3 shows representative defect maps for conventional and innovative rinsing processes. In the conventional process, more defects were detected resulting from post develop residue interacting with the deionized water rinse. Spinning the wafer for a period prior to introducing the water rinse is shown to decrease these defects.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

Additional general background, which help to show the knowledge of those skilled in the art regarding variations and implementations of the disclosed inventions, may be found in the following documents, all of which are hereby incorporated by reference: Coburn, PLASMA ETCHING AND REACTIVE ION ETCHING (1982); HANDBOOK OF PLASMA PROCESSING TECHNOLOGY (ed. Rossnagel); PLASMA ETCHING (ed. Manos and Flamm 1989); PLASMA PROCESSING (ed. Dieleman et al. 1982); Schmitz, CVD) OF TUNGSTEN AND TUNGSTEN SILICIDES FOR VLSI/ULSI APPLICATIONS (1992); METALLIZATION AND METAL-SEMICONDUCTOR INTERFACES (ed. Batra 1989); VLSI METALLIZATION: PHYSICS AND TECHNOLOGIES (ed. Shenai 1991); Murarka, METALLIZATION THEORY AND PRACTICE FOR VLSI AND ULSI (1993); HANDBOOK OF MULTILEVEL METALLIZATION FOR INTEGRATED CIRCUITS (ed. Wilson et al. 1993); Rao, MULTILEVEL INTERCONNECT TECHNOLOGY (1993); CHEMICAL VAPOR DEPOSITION (ed. M. L. Hitchman 1993); and the semiannual conference proceedings of the Electrochemical Society on plasma processing.

What is claimed is:

1. A method for fabricating integrated circuits, comprising the actions of:
(a) wetting an exposed photoresist layer with developer solution;
(b) spinning off said developer solution, to the extent possible without drying any areas of said wafer; and
(c) after at least half of the duration of said step (b), beginning to rinse off the remainder of said developer.

2. The method of claim 1, wherein said developer solution is an organic base.

3. The method of claim 1, wherein said rinsing step uses pure deionized water.

4. A method for fabricating an integrated circuit wafer, comprising the actions of:
(a) wetting an exposed photoresist layer with developer solution;
(b) partially clearing said developer solution from the wafer without rinsing; and
(c) rinsing said developer solution from the wafer, using a rinse solutions;
wherein said actions (b) and (c) are coordinated to minimize the volume of said developer solution which is exposed to said rinse solution.

5. The method of claim 1, wherein said developer solution is an organic base.

6. The method of claim 1, wherein said rinsing step uses pure deionized water.
